(19) United States
(12) Patent Application Publication
(10) Pub. No.: US 2005/0178322 A1
(43) Pub. Date: Aug. 18, 2005

(54) Liquid trap for a vacuum line

(76) Inventor: Andrew P. Nguyen, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/781,225

(22) Filed: Feb. 17, 2004

(51) Int. Cl. B05C 11/02; B05C 13/00; H01L 21/00; B05C 11/00

(52) U.S. Cl. 118/52; 118/56; 430/327; 118/612

(57) ABSTRACT

According to one aspect of the invention, a system for processing semiconductor substrates is provided. A de-gas unit may be connected to a flowing first semiconductor processing fluid to separate the first semiconductor processing fluid into second and third semiconductor processing fluids. The third semiconductor processing fluid may contain gaseous and liquid particles. A liquid trap may be connected to the de-gas unit to catch the liquid particles of the third semiconductor processing fluid. A vacuum supply may be connected to the liquid trap to draw the third semiconductor processing fluid into the liquid trap and further draw the gaseous particles out of the liquid trap.

### BACKGROUND OF THE INVENTION

1). Field of the Invention

This invention relates to a semiconductor substrate processing system including a liquid trap and a method of removing liquid from a vacuum line.

2). Discussion of Related Art

Integrated circuits are formed on semiconductor wafers. The formation of the integrated circuits may include numerous processing steps such as deposition of various layers, etching some of the layers, and multiple bakes.

Often the processing of semiconductor wafers takes place in large wafer processing machines. One of the components found in these machines are known as modules. These modules may receive a semiconductor wafer from a another component, place the wafer on a wafer support, and dispense a liquid, such as a solution or solvent, onto the wafer as one of the many steps included in wafer processing. The liquid may be dispensed onto the wafer from a dispense head that is moved into a position over the wafer. Typically, the liquid is fed into inlets of the dispense head through a valve and dispensed onto the wafer through nozzles on the dispense head.

The liquid is typically fed to the module from a liquid supply canister, which may or may not be a separate component of the system. In order to deliver the liquid to the module, a container of pressurized gas, such as nitrogen, is connected to the liquid supply. As the gas mixes with the liquid, the liquid supply canister also becomes pressurized which forces the liquid from the liquid supply canister. If the liquid were to be dispensed onto the wafer with the nitrogen mixed therein, the wafers can be damaged and defects can occur in the processing of the integrated circuits.

Therefore, a de-gas unit is typically connected between the liquid supply and the module to remove the nitrogen from the liquid. In order to effectively remove the nitrogen from the liquid, the de-gas unit must be connected to a vacuum supply, such as a “house” vacuum.

The de-gas units often do not work perfectly and when the nitrogen is removed from the liquid in the de-gas unit, some of the liquid may be removed as well. Therefore, a gas/liquid mixture may actually be sent to the vacuum supply. If any liquid, or other debris, reaches the vacuum supply, the vacuum supply could be damaged and break down. When the vacuum supply breaks down, the speed at which the wafers can be processed decreases and costs to run the processing facility increases because of the repairs that the vacuum supply requires.

### SUMMARY OF THE INVENTION

The invention provides a system for processing semiconductor substrates. A de-gas unit may be connected to a flowing first semiconductor processing fluid to separate the first semiconductor processing fluid into second and third semiconductor processing fluids. The third semiconductor processing fluid may contain gaseous and liquid particles. A liquid trap may be connected to the de-gas unit to catch the liquid particles of the third semiconductor processing fluid. A vacuum supply may be connected to the liquid trap to draw the third semiconductor processing fluid into the liquid trap and further draw the gaseous particles out of the liquid trap.

### BRIEF DESCRIPTION OF THE DRAWINGS

The invention is described by way of example with reference to the accompanying drawings, wherein:

FIG. 1 is a schematic of a system for processing semiconductor substrates, including a liquid supply subsystem, a de-gas subsystem, and a module stack;

FIG. 2 is a perspective view of a liquid trap within the de-gas subsystem;

FIG. 3 is a cross-sectional side view on 3-3 in FIG. 2 of the liquid trap;

FIG. 4 is a cross-sectional side view of the module stack; and

FIG. 5 is a perspective view of a developer module within the module stack.

### DETAILED DESCRIPTION OF THE INVENTION

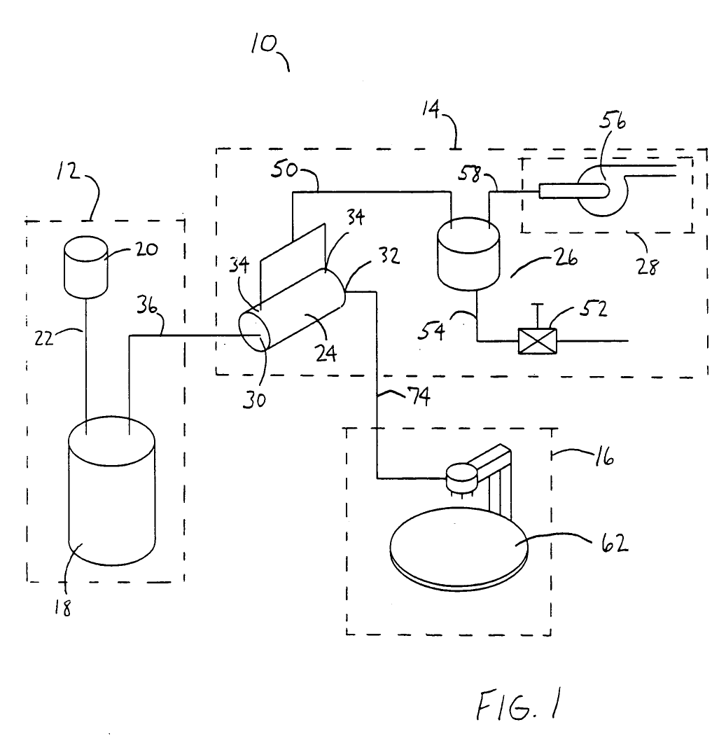

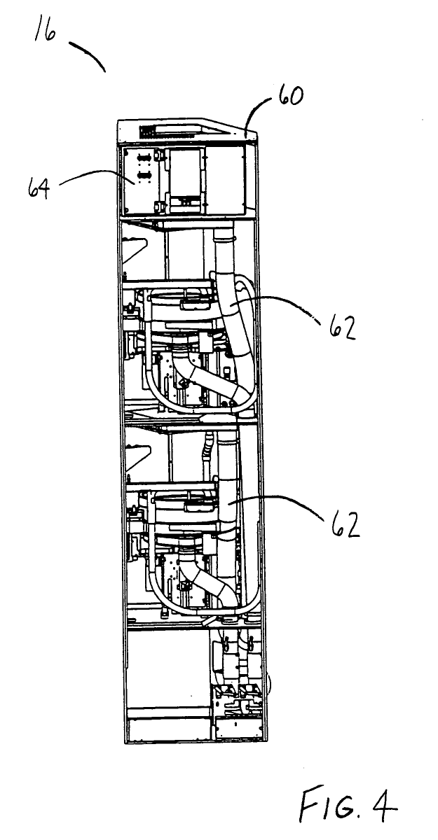

FIG. 1 to FIG. 5 of the accompanying drawings illustrate a system for processing semiconductor substrates. A de-gas unit may be connected to a flowing first semiconductor processing fluid to separate the first semiconductor processing fluid into second and third semiconductor processing fluids. The third semiconductor processing fluid may contain gaseous and liquid particles. A liquid trap may be connected to the de-gas unit to catch the liquid particles of the third semiconductor processing fluid. A vacuum supply may be connected to the liquid trap to draw the third semiconductor processing fluid into the liquid trap and further draw the gaseous particles out of the liquid trap.

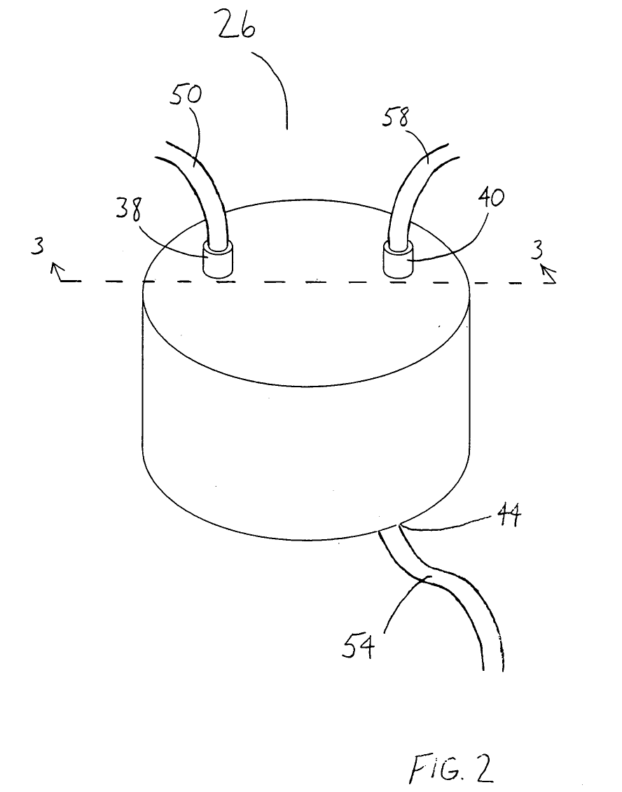

FIGS. 1 and 2 illustrate a semiconductor substrate processing system 10. In an embodiment, the processing system 10 may include a liquid supply subsystem 12, a de-gas subsystem 14, and a module stack 16.

Referring to FIG. 1, the liquid supply subsystem 12 may include a liquid supply canister 18 and a pressurized gas canister 20. The liquid supply canister 18 may be a substantially cylindrical container having a pressurized gas inlet and a fluid outlet at an upper end thereof. The liquid supply canister 18 may contain a semiconductor processing liquid, such as a photoresist developer solvent. The pressurized gas canister 20 may be a substantially cylindrical container with a pressurized gas outlet and may contain a pressured gas, such as nitrogen. The pressurized gas outlet of the pressurized gas canister 20 may be connected to the pressurized gas inlet of the liquid supply canister 18 through a pressurized gas line 22.

The de-gas subsystem 14 may include a de-gas unit 24, a liquid trap 26, and a vacuum supply 28.

In an embodiment, the de-gas unit 24 may be a cylindrically shaped and have a liquid inlet 30, a liquid outlet 32, two de-gas outlets 34, and a de-gassing chamber therein interconnecting the liquid inlet 30, the liquid outlet 32, and the de-gas outlets 34. The liquid inlet 30 and one of the de-gas outlets 34 may be at a first end of the de-gas unit 24, and the liquid outlet 32 and the other de-gas outlet 34 may be at a second end of the de-gas unit 24. The de-gassing chamber may include; a plurality of de-gassing membranes through which gases, but not liquids, may pass, as is commonly understood in the art. The de-gas unit 24 may be connected to the fluid outlet of the liquid supply canister 18 through a supply line 36.

Referring to FIGS. 1, 2, and 3, in an embodiment, the liquid trap 26 may be a hollow, cylindrically shaped canister having a de-gas inlet 38 and a gas outlet 40, at an upper end thereof, a drain outlet 42 at a lower end thereof, and a trap chamber 44 therein interconnecting the de-gas inlet 38, the gas outlet 40, and the drain outlet 42. The liquid trap 26 may, for example, have a diameter 46 of between 5 and 10 inches and a height 48 of between 5 and 10 inches. The liquid trap 26 may be connected to both de-gas outlets 34 of the de-gas unit 24 through a de-gas line 50. The liquid trap 26 may also include a drain valve 52 connected to the drain outlet 42 through a drain line 54.

In an embodiment, the vacuum supply 28 may be created by a pneumatic pump 56 having a low pressure side and a high pressure side. The low pressure side of the pump 56 may be connected to the gas outlet 40 of the liquid trap 26 through a gas line 58. The vacuum supply 28 may be what is known as a “house” vacuum, which is connected to and supplies a vacuum for various other machines besides the de-gas unit 24 at the same time.

In an embodiment, the module stack 16 may include a frame 60, developer modules 62, and a computer controller 64. The developer modules 62 may be vertically stacked and may be substantially identical. The computer controller 64 may lie on top of the developer modules 62 and although not shown in detail, may be electrically connected to the developer modules 62, as well as the other components in the system 10, and include a computer with a memory for storing a set of instructions and a processor connected to the memory for executing the instructions, as is commonly understood in the art.

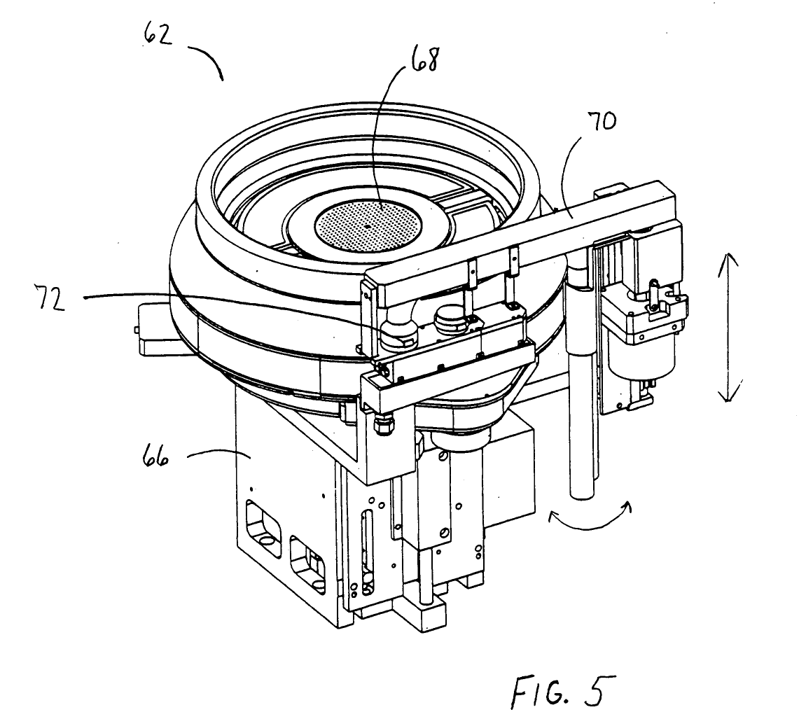

FIG. 5 illustrates one of the developer modules 62. The developer module 62 may include a base 66, a wafer chuck 68, and a dispense arm 70.

The base 66 may be attached to the frame 60 of the module stack 16 and be substantially cubic in shape. The wafer chuck 68, or semiconductor substrate support, may be on top of the base 66, circular in shape, and connected to the base 66 to rotate about a central axis thereof. The wafer chuck 68 may have an upper surface, which although not shown in detail, is substantially flat and in a plane to support a semiconductor substrate or wafer. Although not shown, it should be understood that the base 66 may include an electric motor, or other actuator, to rotate the wafer chuck 68 about the central axis thereof, along with a semiconductor wafer supported by the wafer chuck 68.

The dispense arm 70 may include a dispense head 72, a rotational actuator, and a vertical actuator. As illustrated in FIG. 5, the dispense arm 70 may be attached to the base 66 so that is may translate transverse to the plane of the wafer chuck 68 and rotate over the wafer chuck 68. The dispense head 72 may be attached to an end of the dispense arm 70 that may be suspended over the wafer chuck 68.

The rotational actuator may be an electric motor, or other such suitable actuator, which is connected to the dispense arm 70 to rotate the dispense head 72 back and forth over the wafer chuck 68. The vertical actuator may be a pneumatic actuator, or other such suitable actuator, which is connected to the base 66 and the dispense arm 70 to translate the dispense head 72 transverse to the plane of the wafer chuck 68.

In use, referring to FIG. 5, a semiconductor substrate, such as a wafer that may have a diameter of, for example, 200 or 300 mm, may be placed on the wafer chuck 68 of the developer module 62. The computer controller 16 may control the rotational actuator and the vertical actuator to move the dispense arm 70 so that the dispense head 72 is suspended over the wafer.

Referring to FIG. 1, the gas within the pressurized gas canister 20 may supply the nitrogen to the liquid supply canister 18 through the pressurized gas line 22 and the pressurized gas inlet. The nitrogen may pressurize liquid supply canister, as well as mix with the solvent, so that pressurized solvent, or a first semiconductor processing fluid, is forced out of the liquid outlet on the liquid supply canister 18 through the supply line 36 and into the liquid inlet 30 on the de-gas unit 24. The first semiconductor fluid may be substantially a liquid with gaseous particles mixed therein.

As the solvent passes through the various membranes within the de-gassing chamber of the de-gas unit 24, the nitrogen gas that has become mixed with the solvent may be separated from the solvent. The nitrogen gas, having been separated from the solvent, may then flow out of the de-gassing chamber and be fed into the de-gas outlets 34 on the de-gas unit 24. Due to imperfections in the de-gas unit, the nitrogen gas leaving the de-gas unit, or a second semiconductor processing fluid, may actually be a gas/liquid mixture as it may include some liquid particles, and even droplets, of the solvent. Additionally, it is possible for pieces of the membranes within the de-gassing chamber that have broken free, as well as other debris, to be sent through the de-gas outlets 34. However, solvent which passes through the de-gassing chamber and flows out of the liquid outlet 32 on the de-gas unit 24, or a third semiconductor processing fluid, may be substantially free of nitrogen gas.

The nitrogen free solvent may then flow into the dispense head 72 on the dispense arm 70 of developer module 62 in the module stack 16 through the liquid line 74 and be dispensed onto the wafer.

Referring again to FIG. 1, because the low pressure side of the pump 56 is connected to the de-gas outlets 34 on the de-gas unit 24 through the liquid trap 26, the de-gas outlets 34 may be exposed to a vacuum created by the pump 56. The gas/liquid mixture may thus be drawn out of the de-gas unit 24 through the de-gas outlets 34 and into the de-gas line 50.

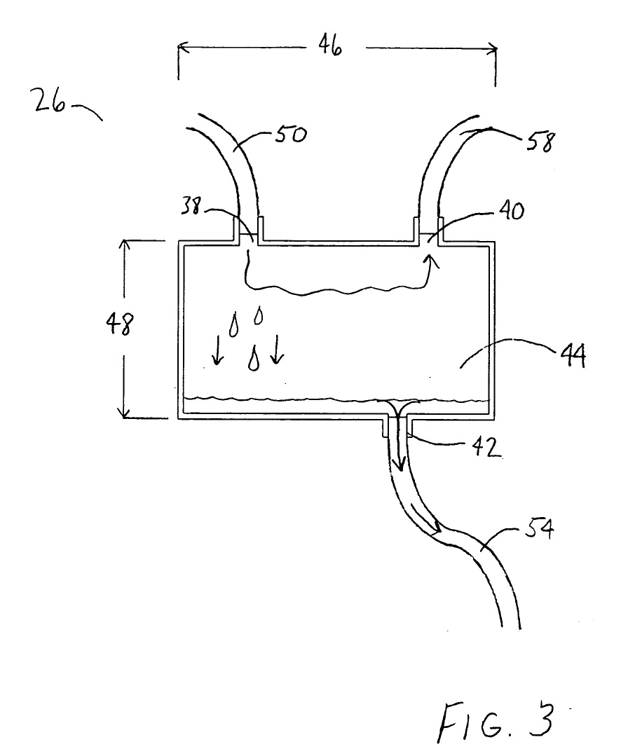

Referring to FIG. 3, the gas/liquid mixture may then flow through the de-gas inlet 38 and into the trap chamber 44 of the liquid trap 26. As the gas/liquid mixture enters the trap chamber 44, the liquid particles and droplets, as well as any other debris, are separated from nitrogen gas. This separation occurs due to the positioning of the de-gas inlet 38 and gas outlet 40, as well as the fact that the liquid particles and droplets are heavier than the nitrogen gas. The liquid particles and droplets, along with any other debris, fall to the bottom of the trap chamber 44 while the nitrogen gas continues to flow toward the vacuum supply 28 through the gas outlet 40 and the gas line 58. No liquid flows through the gas outlet 40 and gas line 58 towards the vacuum supply 28.

When the nitrogen gas reaches the vacuum supply 28, the nitrogen gas may be either disposed of or stored to be recycled.

Referring to FIGS. 1 and 3, the liquid trapped in the liquid chamber 44 may be drained at any time by opening the drain valve 52. Once the drain valve 52 is open, the liquid within the liquid chamber 44 flows through the drain outlet 44 and through the drain valve 52. The liquid may then flow to a disposal or to storage for recycling.

One advantage is that because the liquid trap stops any liquid, or other debris, from entering the vacuum supply, the vacuum supply is less likely to break down. Therefore, the overall speed at which wafers may be processed is increased and the maintenance costs of the processing facility are reduced.

Other embodiments may use other types of liquid traps such as liquid traps that incorporate additional membranes and/or filters to prevent any liquid from entering the vacuum supply. The liquid trap may be used in connection with other various types of semiconductor substrate processing machines that utilize semiconductor processing fluids, such as photoresist coater modules. The liquid in the liquid supply may be other types of semiconductor processing fluids, such as photoresist.

While certain exemplary embodiments have been described and shown in the accompanying drawings, it is to be understood that such embodiments are merely illustrative and not restrictive of the current invention, and that this invention is not restricted to the specific constructions and arrangements shown and described since modifications may occur to those ordinarily skilled in the art.

1. A semiconductor substrate processing system comprising:
a de-gas unit to separate a first flowing semiconductor processing fluid into second and third semiconductor wafer processing fluids;
a liquid trap connected to the de-gas unit to separate the second wafer processing fluid into a gas and a liquid and catch the liquid; and
a vacuum supply connected to the liquid trap to draw the third wafer processing fluid into the liquid trap and further draw the gas out of the liquid trap.

2. The semiconductor substrate processing system of claim 1, wherein the vacuum supply only draws the gas out of the liquid trap.

3. The semiconductor substrate processing system of claim 2, wherein the gas contains substantially no liquid.

4. The semiconductor substrate processing system of claim 3, further comprising a valve connected to the liquid trap to drain any liquid within the liquid trap when the valve is open.

5. The semiconductor substrate processing system of claim 4, wherein the liquid trap further comprises a first opening, a second opening, and a trap chamber therein interconnecting the first and second openings, the second semiconductor processing fluid flowing into the first opening and the gas flowing out of the second opening.

6. The semiconductor substrate processing system of claim 5, wherein the first and second openings of the liquid trap are at an upper end thereof, the liquid falling to a bottom of the chamber.

7. The semiconductor substrate processing system of claim 6, further comprising a liquid supply to supply the first semiconductor processing fluid to the de-gas unit.

8. The semiconductor substrate processing system of claim 7, wherein the first semiconductor processing fluid is substantially a liquid with gaseous particles mixed therein.

9. The semiconductor substrate processing system of claim 8, further comprising a pressurized gas supply connected to the liquid supply to pressurize the liquid such that the liquid flows into the de-gas unit.

10. The semiconductor substrate processing system of claim 9, further comprising a semiconductor substrate processing apparatus having a dispense head, the dispense head being connected to the de-gas unit to dispense the third semiconductor processing fluid onto a semiconductor substrate.

11. The semiconductor substrate processing system of claim 10, wherein the first semiconductor includes photoresist developer solvent.

12. A semiconductor substrate processing system comprising:
a de-gas unit to separate a first flowing semiconductor processing fluid into second and third wafer processing fluids, the second wafer processing fluid including gaseous and liquid particles;
a liquid trap connected to the de-gas unit to catch the liquid particles of the second wafer processing system; and
a vacuum supply connected to the liquid trap to draw the second wafer processing fluid into the liquid trap and further draw the gaseous particles out of the liquid trap.

13. The semiconductor substrate processing system of claim 12, wherein the vacuum supply only draws the gas out of the liquid trap.

14. The semiconductor substrate processing system of claim 13, wherein the gas contains substantially no liquid.

15. The semiconductor substrate processing system of claim 14, further comprising a valve connected to the liquid trap to drain any liquid within the liquid trap when the valve is open.

16. The semiconductor substrate processing system of claim 15, wherein the liquid trap further comprises a first opening, a second opening, and a trap chamber therein interconnecting the first and second openings, the second semiconductor processing fluid flowing into the first opening and the gas flowing out of the second opening.

17. The semiconductor substrate processing system of claim 16, wherein the first and second openings of the liquid trap are at an upper end thereof, the liquid falling to a bottom of the chamber.

18. The semiconductor substrate processing system of claim 17, further comprising a liquid supply to supply the first semiconductor processing fluid to the de-gas unit.

19. The semiconductor substrate processing system of claim 18, wherein the first semiconductor processing fluid is substantially a liquid with gaseous particles mixed therein.

20. The semiconductor substrate processing system of claim 19, further comprising a pressurized gas supply connected to the liquid supply to pressurize the liquid such that the liquid flows into the de-gas unit.

21. The semiconductor substrate processing system of claim 20, further comprising a semiconductor substrate processing apparatus having a dispense head, the dispense head being connected to the de-gas unit to dispense the third semiconductor processing fluid onto a semiconductor substrate.

22. The semiconductor substrate processing system of claim 21, wherein the first semiconductor processing fluid includes photoresist developer solvent.

23. A semiconductor substrate processing system comprising:
a de-gas unit having an inlet, at least one outlet, and a de-gassing chamber therein interconnecting the inlet and the at least one outlet, a first semiconductor processing fluid flowing into the inlet and being separated into a second semiconductor processing fluid and a third semiconductor processing fluid within the de-gassing chamber, the second semiconductor processing fluid flowing out through the at least one outlet;
a liquid trap having a first opening, a second opening, and a chamber therein interconnecting the first and second openings, the first opening being connected to the at least one outlet of the de-gas unit; and
a pump having a low pressure side and a high pressure side, the low pressure side connected to the second opening of the liquid trap causing the third semiconductor processing fluid to flow into the first opening of the liquid trap, the liquid trap shaped such that the second semiconductor processing fluid is separated into a liquid and a gas, the liquid being caught in the chamber of the liquid trap and the gas flowing out of the second opening into the low pressure side of the pump.

24. The semiconductor substrate processing system of claim 23, wherein the vacuum supply only draws the gas out of the liquid trap.

25. The semiconductor substrate processing system of claim 24, wherein the gas contains substantially no liquid.

26. The semiconductor substrate processing system of claim 25, further comprising a valve connected to the liquid trap to drain any liquid within the liquid trap when the valve is open.

27. The semiconductor substrate processing system of claim 26, further comprising a semiconductor substrate processing apparatus having a dispense head, the dispense head being connected to the de-gas unit to dispense the third semiconductor processing fluid onto a semiconductor substrate.

28. A semiconductor substrate processing system comprising:
a semiconductor substrate processing apparatus having a dispense head;
a liquid supply containing a first semiconductor processing fluid;
a supply line interconnecting the dispense head and the liquid supply to flow the first semiconductor processing fluid from the liquid supply to the dispense head;
a de-gas unit connected to the supply line between the liquid supply and the dispense head to separate the first semiconductor processing fluid into second and third semiconductor processing fluids, the second semiconductor processing fluid including gaseous and liquid particles, the third semiconductor processing fluid flowing into the dispense head on the semiconductor substrate processing apparatus;
a liquid trap connected to the de-gas unit to catch the liquid particles of the second semiconductor processing fluid; and
a vacuum supply connected to the liquid trap to draw the third wafer processing fluid into the liquid trap and further draw the gaseous particles of the second semiconductor processing fluid out of the liquid trap.

29. A method comprising:
separating a first semiconductor processing fluid into second and third semiconductor processing fluids, the third semiconductor processing fluid being substantially a liquid; and
separating the second semiconductor processing fluid into a gas and a liquid.

30. The method of claim 29, further comprising dispensing the third semiconductor processing fluid onto a semiconductor substrate.

31. The method of claim 30, further comprising mixing the gas with the liquid to form the first semiconductor processing fluid.

32. A method comprising:
mixing a pressurized gas with a liquid to form a first semiconductor processing fluid, the first semiconductor processing fluid flowing into a de-gas unit;
separating the first semiconductor processing fluid into second and third semiconductor processing fluids within the de-gas unit, the second semiconductor processing fluid having gaseous and liquid particles and flowing into a liquid trap, the third semiconductor processing fluid being substantially a liquid and flowing into a semiconductor substrate processing apparatus;
trapping the liquid particles of the second semiconductor processing in the liquid trap;
flowing the gaseous through the liquid trap into a vacuum supply; and
dispensing the third semiconductor fluid onto a semiconductor substrate.
